(19) United States
(12) Patent Application Publication
(10) Pub. No.: US 2015/0228847 A1
(43) Pub. Date: Aug. 13, 2015

(54) HIGH-LUMINANCE NITRIDE LIGHT-EMITTING DEVICE AND METHOD FOR MANUFACTURING SAME

(71) Applicant: ILJIN LED CO., LTD., Ansan-si Gyeonggi-do (KR)

(72) Inventor: Norikatsu Koide, Nagoya (JP)

(21) Appl. No.: 14/428,124

(22) PCT Filed: Sep. 13, 2013
(86) PCT No.: PCT/KR2013/008304

§ 371 Date: Mar. 13, 2015

(30) Foreign Application Priority Data
Sep. 14, 2012 (KR) 10-2012-0102459

(51) Int. Cl. H01L 33/00; H01L 33/32; H01L 33/38; H01L 33/42

(52) U.S. Cl. CPC H01L 33/0075; H01L 33/42; H01L 33/0079; H01L 33/32; H01L 33/385; H01L 2933/0016

(57) ABSTRACT

Disclosed are a nitride light-emitting device having high luminance even while saving on manufacturing costs by using a silicon substrate as a growth substrate, and a method for manufacturing the same. A nitride light-emitting device according to the present invention comprises: a light-emitting structure comprising, from the top down, a first nitride semiconductor layer, an active layer, and a second nitride semiconductor layer and having a plurality of trenches from the bottom up to at least the second nitride semiconductor layer and the active layer; and a bonding substrate combined to a lower surface of the light-emitting structure, wherein a width of the light-emitting structure between the trenches is 20-300 mm.

### TECHNICAL FIELD

The present invention relates to a nitride light-emitting device, and more particularly to a nitride light-emitting device, which has high luminance and can be fabricated at low costs using a silicon (Si) substrate as a substrate for semiconductor growth, and to a fabrication method thereof.

### BACKGROUND ART

A light-emitting device is a device that emits light upon the recombination of electrons and holes. Typical light-emitting devices include a nitride semiconductor light-emitting device based on a nitride semiconductor represented by GaN. The nitride semiconductor light-emitting device has a high band gap, and thus can emit various colored lights. In addition, it has excellent thermal stability, and thus has been used in various fields.

Light-emitting devices based on nitride semiconductors have generally been fabricated by an epitaxial growth process using a sapphire substrate in place of an expensive GaN substrate.

A sapphire substrate is used mainly as a substrate for nitride growth, because the growth of a nitride thin film thereon is relatively easy and the sapphire substrate is stable at high temperatures. However, it is also relatively expensive, and thus results in an increase in the fabrication cost.

For this reason, in recent years, nitride light-emitting devices based on a silicon (Si) substrate that can provide a large-area substrate at low costs have been developed. However, the silicon substrate has a problem in that the crystallinity of a nitride semiconductor growing on the silicon substrate is reduced due to the lattice mismatch between the nitride semiconductor having a hexagonal crystalline structure and silicon having a cubic crystalline structure. In addition, when the silicon substrate is used, a high-quality nitride semiconductor crystal cannot be obtained due to the threading dislocation of a nitride layer, which occurs in a direction perpendicular to the surface of the substrate, and there is a limit to increasing the luminance of the light-emitting device.

Prior art documents related to the present invention include Japanese Unexamined Patent Publication No. 2008-277430 (published on Nov. 13, 2008), which discloses a nitride light-emitting device including a group III nitride layer (GaN layer) grown on a silicon substrate in a lateral direction by the use of ELO mask patterns made of a carbon material.

### DISCLOSURE

### Technical Problem

It is an object of the present invention to a nitride light-emitting device that has high luminance and, at the same time, is fabricated at reduced costs using a silicon (Si) substrate as a growth substrate, and a method for fabricating the nitride light-emitting device.

### Technical Solution

In an embodiment of the present invention, a method for fabricating a nitride light-emitting device includes the steps of: forming mask patterns having a width of 20-300 μm on a silicon substrate; laterally growing a nitride on the silicon substrate exposed between the mask patterns, thereby forming a light-emitting structure including a first nitride semiconductor layer, an active layer and a second nitride semiconductor layer; etching at least the second nitride semiconductor layer and the active layer in regions of the light-emitting structure between the mask patterns to form trenches; attaching a bonding substrate to the surface of the light-emitting structure having the trenches formed therein; and removing the silicon substrate and the mask patterns.

In another embodiment of the present invention, a nitride light-emitting device includes: a light-emitting structure including a first nitride semiconductor layer, an active layer and a second nitride semiconductor layer from top to bottom, in which a plurality of trenches are formed at least in the second nitride semiconductor layer and the active layer; and a bonding substrate bonded to the bottom surface of the light-emitting structure, wherein the width of the light-emitting structure between one trench and another trench adjacent thereto is 20-300 μm.

### Advantageous Effects

The nitride light-emitting device according to the present invention includes trenches formed by etching the active layer of the light-emitting structure including the nitride layers laterally grown on the silicon substrate. Thus, the threading dislocation of the nitride layers, which occur in a direction perpendicular to the surface of the silicon substrate, and a non-light-emitting area, can be reduced, thereby increasing the luminous efficiency and luminance of the nitride light-emitting device.

Moreover, because the trenches are formed, air on the bonding surface can move to the trenches and disappear during the attachment of the bonding substrate, and thus the formation of bubbles on the bonding surface can be prevented, thereby increasing the chip yield.

When an insulating layer is further formed on the surface of the trenches, the flow of electric current in regions having the trenches formed therein can be prevented, and light leaking from the sidewall of the mesa-etched trenches can be effectively used, and thus the luminance of the nitride light-emitting device can further be increased.

In addition, according to the present invention, even when a relatively inexpensive silicon (Si) substrate is used as a substrate for semiconductor growth, a high-luminance nitride semiconductor device can be fabricated, and the fabrication cost thereof can be reduced.

### BRIEF DESCRIPTION OF DRAWINGS

FIG. 1 is a perspective view showing a nitride light-emitting device according to an embodiment of the present invention.

FIGS. 2 to 7 are perspective views showing a method for fabricating a nitride light-emitting device according to an embodiment of the present invention.

FIG. 8 is a perspective view showing another embodiment of mask patterns that are used in the present invention.

FIG. 9 is a perspective view showing trenches formed in a light-emitting structure when using the mask patterns shown in FIG. 8.

FIGS. 10 and 11 are perspective views showing a process of depositing and etching an insulating layer on a light-emitting structure, which includes the trenches shown in FIG. 4, before the attachment of a bonding substrate.

FIG. 12 is a perspective view showing another embodiment of the insulating layer patterns shown in FIG. 11.

FIGS. 13 and 14 are perspective views showing a process of depositing and etching an insulating layer on a light-emitting structure, which includes the trenches shown in FIG. 9, before the attachment of a bonding substrate.

FIG. 15 is a perspective view showing another embodiment of the insulating layer patterns shown in FIG. 14.

FIG. 16 shows an example of a diced nitride light-emitting device according to an embodiment of the present invention.

### MODE FOR INVENTION

Hereinafter, a high-luminance nitride light-emitting device and a fabrication method thereof according to preferred embodiments of the present invention will be described in further detail with reference to the accompanying drawings.

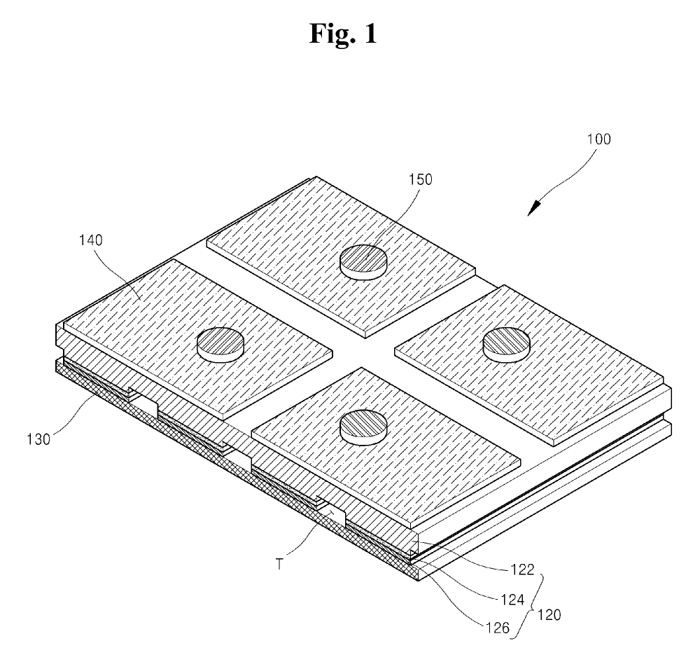

FIG. 1 is a perspective view showing a nitride light-emitting device according to an embodiment of the present invention.

Referring to FIG. 1, a nitride light-emitting device 100 according to an embodiment of the present invention includes a light-emitting structure 120 and a bonding substrate 130. In addition, the nitride light-emitting device 100 according to the present invention may include transparent conductive patterns 140 and n-side bonding pads 150.

The light-emitting structure 120 includes a first nitride semiconductor layer 122, an active layer 124 and a second nitride semiconductor layer 126 from top to bottom, and a plurality of trenches T may be formed at least in the first nitride semiconductor layer 126 and the active layer 124.

The first and second nitride semiconductor layers 122 and 126 and the active layer 124 are laterally grown on a silicon (Si) substrate to have a certain orientation.

Specifically, the first and second nitride semiconductor layers 122 and 126 may be made of a semiconductor material, which is represented by a composition formula of AlₓIn_{y}Ga_{(1-x-y)}N (0≦x≦1, 0≦y≦1, and 0≦x+y≦1) and is doped with an n-type impurity and a p-type impurity. Examples of this semiconductor material include nitrides such as GaN, AlGaN, InGaN or the like. Meanwhile, the n-type impurity that is used in the present invention may be Si, Ge, Se, Te or the like, and the p-type impurity that is used in the present invention may be Mg, Zn, Be or the like.

The first and second nitride semiconductor layers 122 and 126 may be n-type and p-type semiconductor layers, respectively, but are not limited thereto, and may also be p-type and n-type semiconductor layers, respectively.

The first nitride semiconductor layer 122 preferably has a resistance of 0.02 Ω·cm to 0.1 Ω·cm and a carrier concentration of 2×10¹⁷ cm³ to 1×10¹⁸ cm³ in a portion ranging from the surface to a depth of 30-500 nm therefrom in order to ensure uniform current spreading.

The active layer 124 formed between the first and second nitride semiconductor layers 122 and 126 emits light having a certain level of energy by the recombination of electrons and holes, and may have a multi-quantum-well (MQW) structure consisting of alternating quantum well layers and quantum barrier layers. The multi-quantum-well structure may be an InGaN/GaN structure.

One surface of the bonding substrate 130 is bonded to the lower surface of the light-emitting structure 120, that is, the bottom surface of the second nitride semiconductor layer 126. Herein, the bonding substrate 130 may be a silicon (Si) substrate or a metal substrate, and may act as a p-side electrode.

In the nitride light-emitting device 100 according to the embodiment of the present invention, a separate p-side electrode may be formed, but may also be omitted if the bonding substrate 130 acts as a p-side electrode.

Generally, a GaN layer laterally grown on a silicon substrate is likely to dislocate in a direction perpendicular to the surface of the silicon substrate due to its lattice mismatch with silicon, resulting in a threading dislocation in the light-emitting structure. As a result, when an electrode is formed on the light-emitting structure, leakage current may flow, and a voltage cannot be applied throughout the light-emitting device.

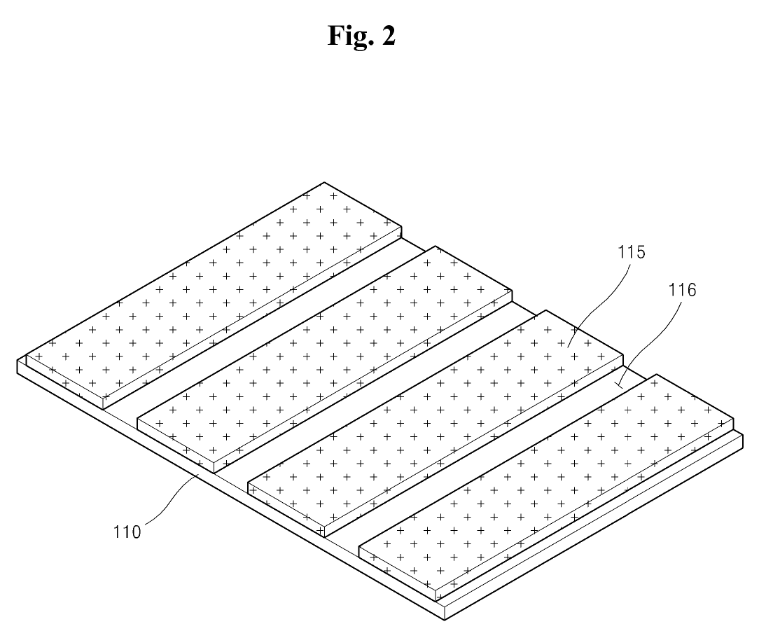

The light-emitting structure 120 that is applied to the present invention is formed by removing threading dislocations, formed by epitaxial growth on the silicon substrate from mask windows (see 116 in FIG. 2) between mask patterns (see 115 in FIG. 2), using trench (T) structures.

For this purpose, the trenches T preferably have a width of 5-40 μm, like the mask windows (see 116 in FIG. 2) between the mask patterns (see 115 in FIG. 2). If the width of the trench T is less than 5 μm, the width of the mask window (see 116 in FIG. 2) corresponding to the trench T will become narrower, and a long growth time will be required for lateral growth, and if the width of the trench T is more than 40 μm, the light extraction efficiency can be reduced due to a decrease in the light-emitting area.

When the width of the trench T is controlled as described above, the non-light-emitting area can be reduced, and thus a nitride light-emitting device having high luminance can be provided.

According to the present invention, threading dislocation can be reduced by forming the trenches T, so that the light extraction efficiency of the light-emitting structure 120 can be increased. Thus, a nitride light-emitting device having high luminance can be provided.

In addition, when the trenches T are formed, air on the bonding surface will move to the trenches T and disappear during the attachment of the bonding substrate 130, and thus the formation of bubbles on the bonding surface can be prevented, thereby increasing the chip yield.

Particularly, according to the present invention, the width of the light-emitting structure 120 between one trench T and another trench T adjacent thereto can be determined by taking into consideration the width of the mask pattern formed on the silicon substrate. For example, the width of the light-emitting structure 120 is preferably 20-300 μm.

If the width of the light-emitting structure 120 is less than 20 μm, the light extraction efficiency can be reduced due to a decrease in the light-emitting area, and if the width is more than 300 μm, the device productivity can be reduced.

The light-emitting structure 120 between one trench T and another trench T adjacent thereto may be formed of a stripe pattern or a block pattern. In addition, although not shown in the figure, the light-emitting structure 120 may also have an inclined sidewall by mesa etching such that the width thereof decreases downward.

As shown in the figure, the trenches T may be formed by etching not only the second nitride semiconductor layer 126 and the active layer 124, but also a portion of the first nitride semiconductor layer 122.

Meanwhile, although not shown in the figure, the light-emitting structure 120 may further include a buffer layer (not shown) made of aluminum nitride (AlN) on the first nitride semiconductor layer 122 in order to reduce lattice defects resulting from the growth of the first nitride semiconductor layer 122 on the silicon (Si) substrate.

In addition, the light-emitting structure 120 may further include an electron blocking layer (EBL; not shown) such as Mg-doped AlGaN between the active layer 124 and the second nitride semiconductor layer 126.

As shown in the figure, the nitride light-emitting device 100 may further comprise a plurality of transparent conductive patterns 140, which are spaced at a predetermined distance from one another, on the top surface of the light-emitting structure 120, that is, the top surface of the first nitride semiconductor layer 122. The transparent conductive patterns 140 may be made of an ohmic contact layer formed of, for example, a material including indium tin oxide (ITO).

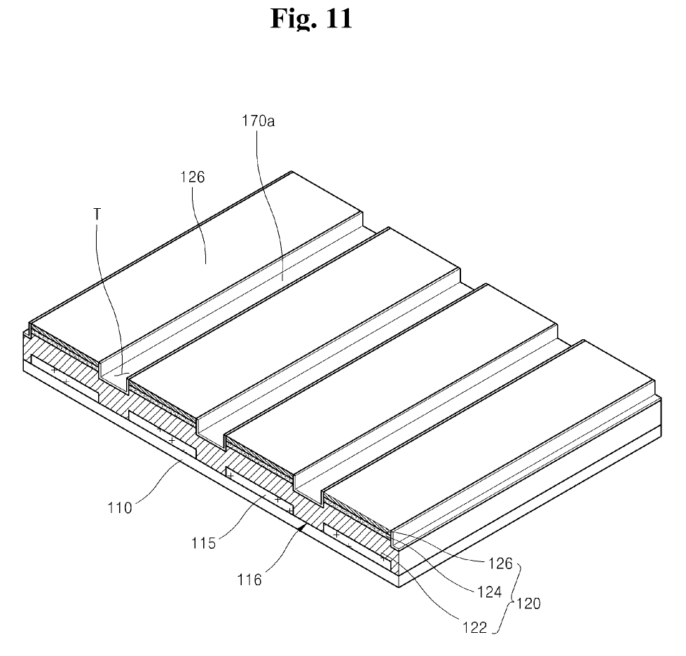

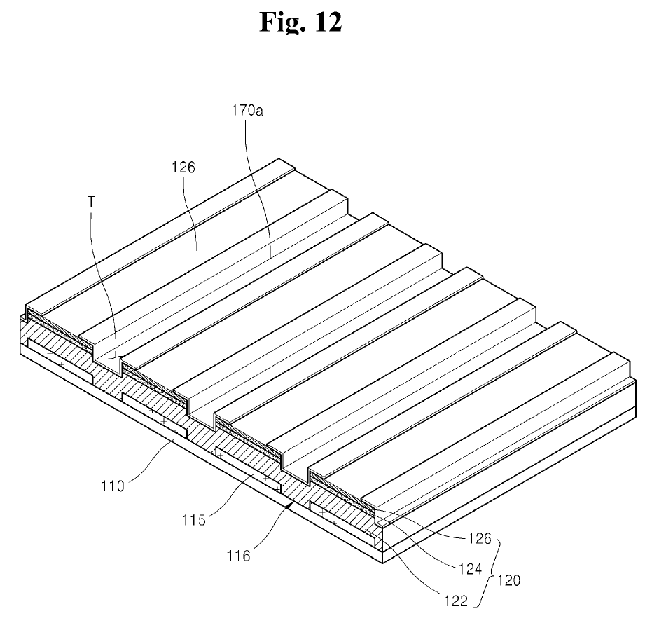

The nitride light-emitting device 100 according to the embodiment of the present invention preferably further includes insulating layer patterns (see 170a in FIG. 11) on the surface of the trenches T, that is, the bottom surface and sidewall of the trenches T, because the flow of electric current in a region having the trenches T formed therein may occur. More preferably, the nitride light-emitting device 100 may further include insulating layer patterns (see 170a in FIG. 12) formed not only on the surfaces of the trenches T, but also on the edge of the bottom of the light-emitting structure 120.

For example, the insulating layer patterns may be formed of silicon oxide (SiO₂). Meanwhile, if the sidewall of the trenches T is a mesa-etched sidewall (inclined sidewall), the insulating layer pattern may have a multilayer structure consisting of alternating silicon oxide (SiO₂) layers and titanium oxide (TiO₂) layers so that it can be used as a reflective layer. In this case, light leaking from the sidewall of the mesa-etched trenches T can be effectively used, and thus the luminance of the nitride light-emitting device 100 can further be increased.

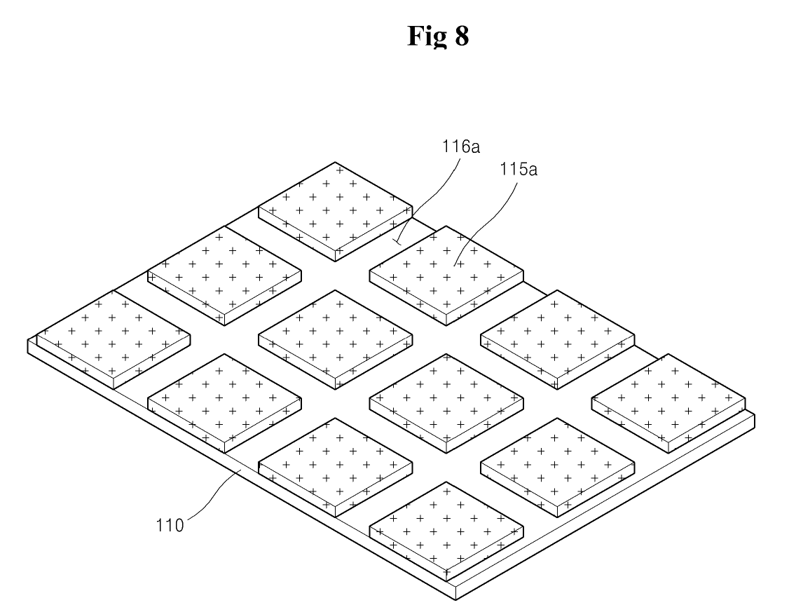

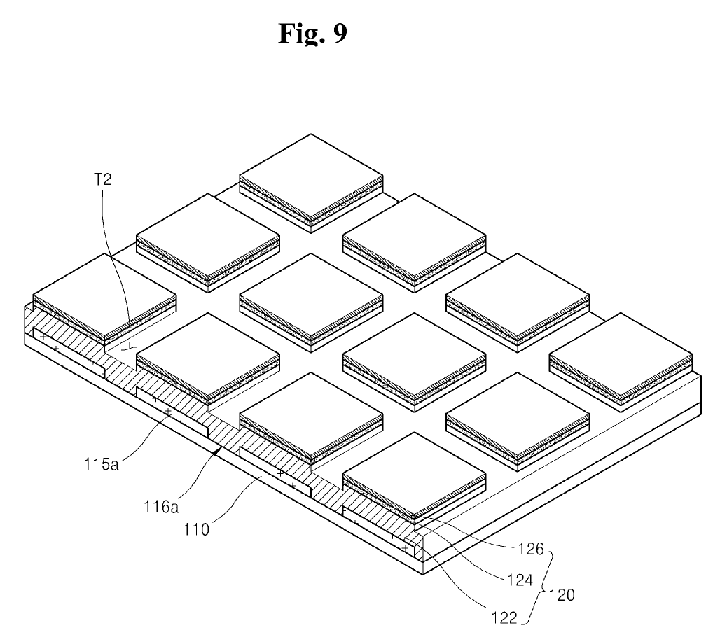

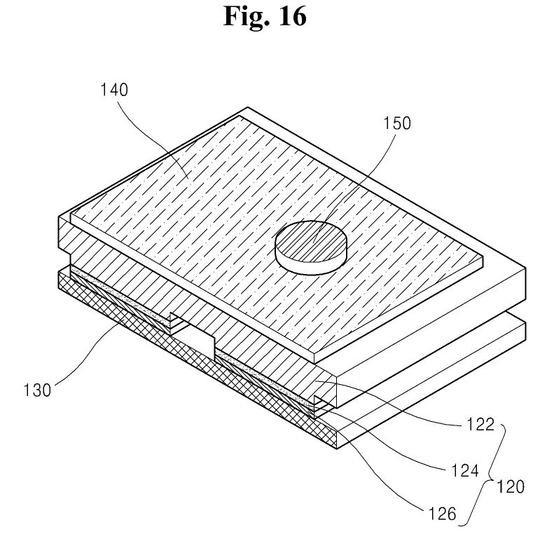

FIGS. 2 to 7 are perspective views showing a method for fabricating a nitride light-emitting device according to an embodiment of the present invention; FIG. 8 is a perspective view showing another embodiment of mask patterns that are used in the present invention; FIG. 9 is a perspective view showing trenches formed in a light-emitting structure when using the mask patterns shown in FIG. 8; and FIG. 16 shows an example of a diced nitride light-emitting device according to an embodiment of the present invention.

Referring to FIG. 2, stripe-shaped mask patterns 115 having a width of 20-300 μm are formed at a distance of 5-40 μm on a silicon substrate 110. Thus, mask windows 116 between the mask patterns 115 have a width of 5-40 μm.

The mask patterns 115 are preferably formed of a material on which a nitride layer does not grow. For example, the mask pattern may be formed of silicon oxide (SiO₂), but is not particularly limited thereto.

If the width of the mask patterns 115 is out of the above range, the lateral growth of a subsequent nitride layer, for example, a GaN layer, can be difficult or insufficient. For this reason, the width of the mask pattern is preferably maintained in the above range.

The mask patterns 115 may be formed by depositing an SiO₂ layer having a thickness of about 50 nm on the silicon substrate 110 by a physical vapor deposition (PVD) or chemical vapor deposition (CVD) process, and patterning the formed SiO₂ layer by a conventional photolithography process. The formation of the mask patterns can be performed using a conventional known process, and thus the detailed description thereof is omitted.

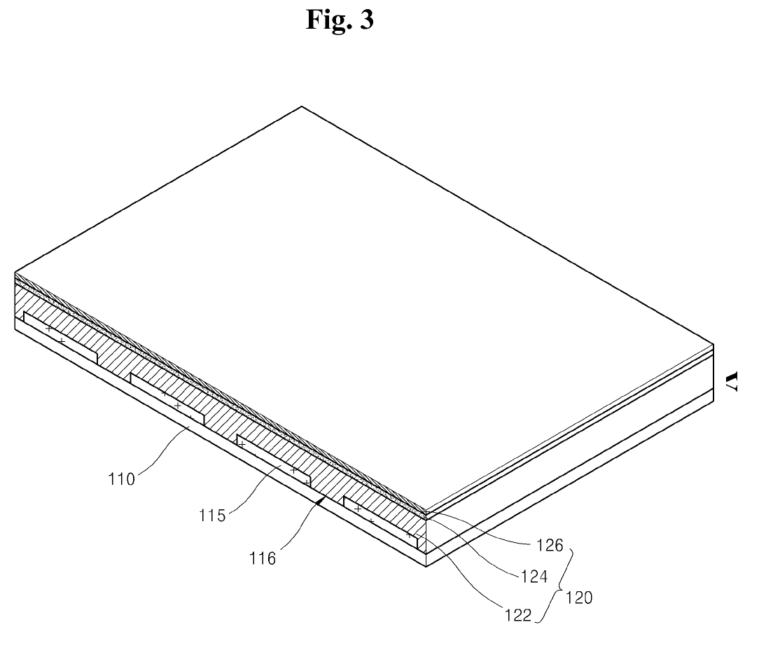

Referring to FIG. 3, a nitride is laterally grown on the silicon substrate 110 exposed between the mask patterns 115 to form a light-emitting structure 120 including a first nitride semiconductor layer 122, an active layer 124 and a second nitride semiconductor layer 126.

The first and second nitride semiconductor layers 122 and 126 and the active layer 124 may be grown using an epitaxial growth process known in the art.

In this case, for example, the growth of GaN for forming the first nitride semiconductor layer 122 is performed by introducing trimethyl gallium (TMG). In this process, GaN crystalline particles grow on the silicon substrate 110 exposed through the mask windows 116 between the mask patterns 115, and then the GaN crystalline particles are connected to one another to form a pyramid-shaped GaN layer on the exposed portions of the silicon substrate 110. Next, when the growth conditions are changed, the lateral growth of the GaN layer is promoted, and finally, an about 3.5-μm-thick flat GaN layer for the first nitride semiconductor layer 122 is obtained.

Thereafter, TMG and trimethyl indium (TMln) may be introduced onto the first nitride semiconductor layer 122 of GaN at a silicon substrate 110 temperature of 750° C., thereby forming a multi-quantum-well (MQW) layer having an InGaN/GaN structure and an emission wavelength of 450 nm, which is the active layer 124.

Next, TMG and Cp₂Mg may be introduced onto the active layer 124 at a silicon substrate 110 temperature of 1100° C. to form an Mg-doped GaN layer having a thickness of about 90 nm, which is the second nitride semiconductor layer 126.

The light-emitting structure 120 may be annealed at a temperature of 700° C. for about 5 minutes.

Meanwhile, before the formation of the first nitride semiconductor layer 122, a buffer layer (not shown) made of aluminum nitride (AlN) is preferably further formed to reduce lattice defects resulting from the growth of the first nitride semiconductor layer 122 on the silicon substrate 110. For example, the AlN buffer layer may be formed to a thickness of about 50 nm by introducing TMA (trimethyl aluminum) and NH₃ at 1100° C. using hydrogen (H₂) as a carrier gas. Alternatively, the buffer layer may also be formed by depositing an AlN layer to a thickness of about 40 nm by sputtering.

In addition, before the formation of the second nitride semiconductor layer 126, an electron blocking layer (not shown) may also be formed by introducing TMA, TMG and Cp₂Mg onto the active layer 124 at a silicon substrate 110 temperature of 1100° C. to form an Mg-doped AlGaN layer having a thickness of about 20 nm.

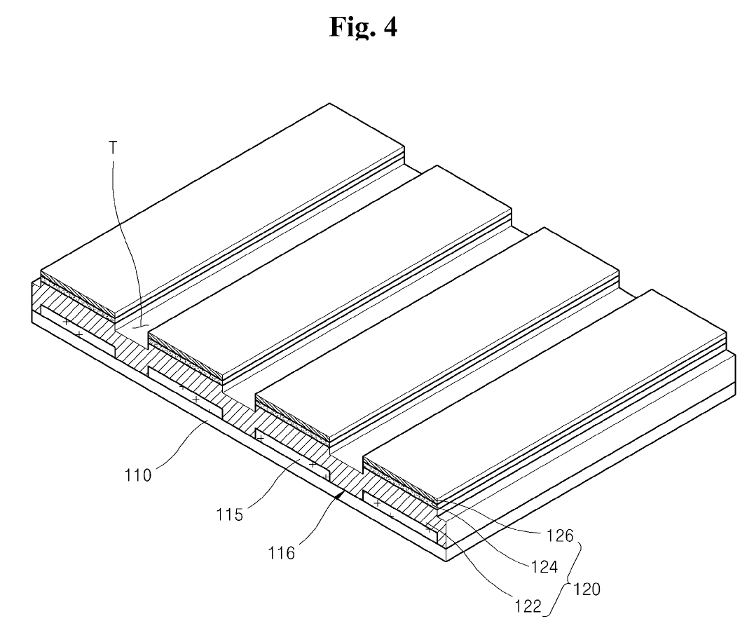

Referring to FIG. 4, a plurality of trenches T are formed by etching at least the second nitride semiconductor layer 126 and the active layer 124 of the light-emitting structure 120, which correspond to portions of the silicon substrate 110 under the mask pattern 115.

For example, the trenches T may be formed by etching at least the second nitride semiconductor layer 126 and the active layer 124 of the light-emitting structure 120, exposed between etch mask patterns (not shown) corresponding to the mask patterns 115, using a method such as inductively coupled plasma (ICP). Herein, the etch mask patterns may be silicon oxide patterns formed by forming a silicon oxide (SiO₂) layer on the light-emitting structure 120 and patterning the formed silicon oxide (SiO₂) layer by a conventional photolithography process so as to correspond to the mask patterns 115.

For example, the silicon oxide patterns may be formed by etching the silicon oxide layer using 10% BHF (buffered HF).

The trenches T are preferably to have a width of 5-40 μm. If the width of the trenches T is less than 5 μm, the width of the mask windows 116 corresponding to the trenches T will become narrower, and a long growth time will be required for lateral growth, and if the width of the trenches T is more than 40 μm, the light extraction efficiency can be reduced due to a decrease in the light-emitting area.

Thus, the light-emitting structure 120 between one trench T and another trench T adjacent thereto may be formed as a stripe pattern having a width of 20-300 μm.

Meanwhile, it is to be understood that the trenches T may be formed by etching from the second nitride semiconductor layer 126 to a portion of the first nitride semiconductor layer 122.

In addition, the trenches T may also be formed by mesa etching such that the sidewall thereof is inclined.

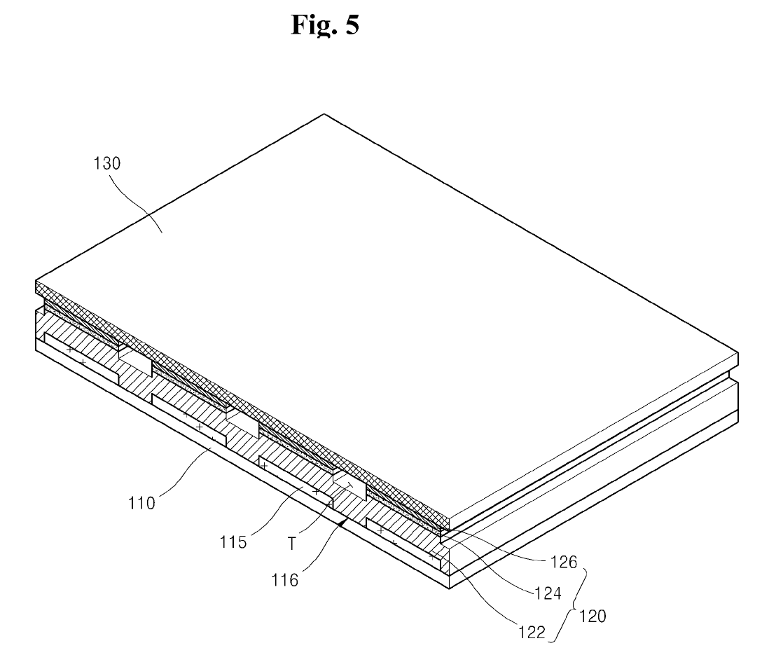

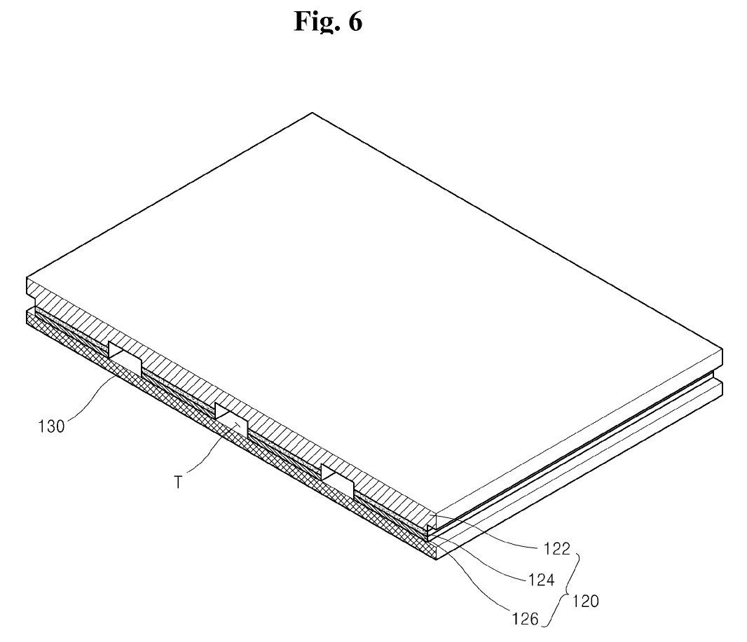

Referring to FIGS. 5 and 6, a bonding substrate 130 is attached to the surface of the light-emitting structure 120 having the trenches T formed therein.

Herein, one surface of the bonding substrate 130 may be attached to the surface of the exposed portion of the second nitride semiconductor layer 126 using anisotropic conductive paste or lead. As the bonding substrate 130, a semiconductor substrate exemplified by a silicon substrate or a metal substrate may be used.

Meanwhile, before the bonding substrate 130 is attached to the surface of the light-emitting structure 120, chemical surface treatment for activating the surface of the exposed portion of the second nitride semiconductor layer 126 may be performed.

Next, the silicon substrate 110 and the mask patterns 115 are removed. The silicon substrate 110 and the mask patterns 115 may be removed by a chemical mechanical polishing (CMP) or etching process. As a result, one surface of the first nitride semiconductor layer 122 is exposed.

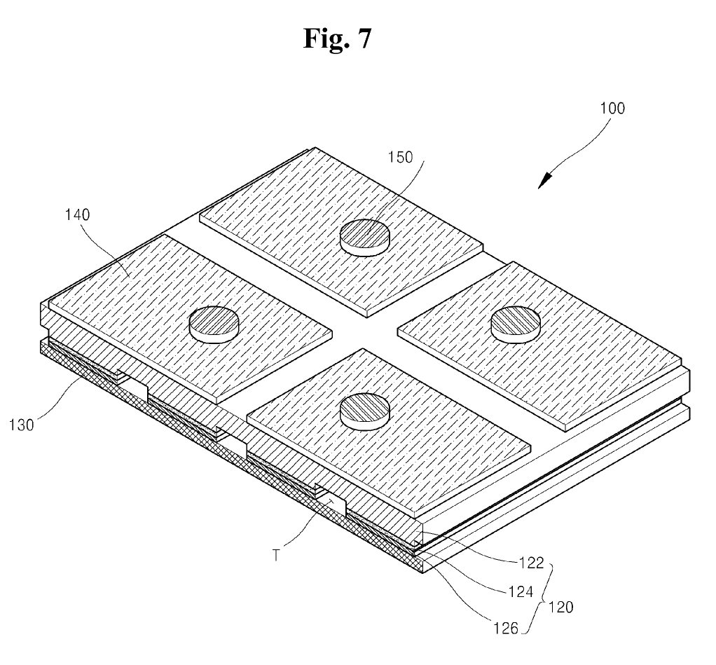

Referring to FIG. 7, a transparent conductive pattern 140 and an n-side bonding pad 150 are formed on the exposed portion of the first nitride semiconductor layer 122.

Specifically, ITO or the like is deposited on the exposed portion of the first nitride semiconductor layer 122 by a method such as sputtering to form a transparent electrode layer, which is then patterned using a mask (not shown) to form transparent conductive patterns 140.

Next, an n-side bonding pad 150 is formed on a portion of the transparent conductive pattern 140. The n-side bonding pad 150 may be formed using a conventional method known in the art. For example, it may be formed on a portion of the transparent conductive pattern 140 by depositing a metal layer or metal alloy layer including Cr, Al, Ni, Au or the like using a conventional PVD, CVD or MOCVD method, and patterning the deposited layer using a mask (not shown).

Meanwhile, the transparent conductive pattern 140 may be omitted. In this case, the n-side bonding pad 150 may be formed on the exposed portion of the first nitride semiconductor layer 122.

Next, the chip may be separated by dicing and cutting using a laser, thereby fabricating a light-emitting cell as shown in FIG. 16.

Meanwhile, as shown in FIG. 8, unlike the mask patterns 115 shown in FIG. 2, block-shaped second mask patterns 115a having a width of 20-300 μm may be formed at a distance of 5-40 μm on the silicon substrate 110. In this case, second mask windows 116a have a width of 5-40 μm.

Herein, the second mask patterns 115a provide the effect of increasing the area of the silicon substrate 110 exposed through the mask window 116a between the mask patterns 115a, compared to the mask patterns 115a shown in FIG. 2, thereby reducing the time required for the lateral growth of nitride layers in subsequent processes.

If the block-shaped second mask patterns 115a shown in FIG. 8, a light-emitting structure 120 between one second trench T2 and another second trench T2 adjacent thereto as shown in FIG. 9 may be formed of a block pattern having a width of 20-300 μm.

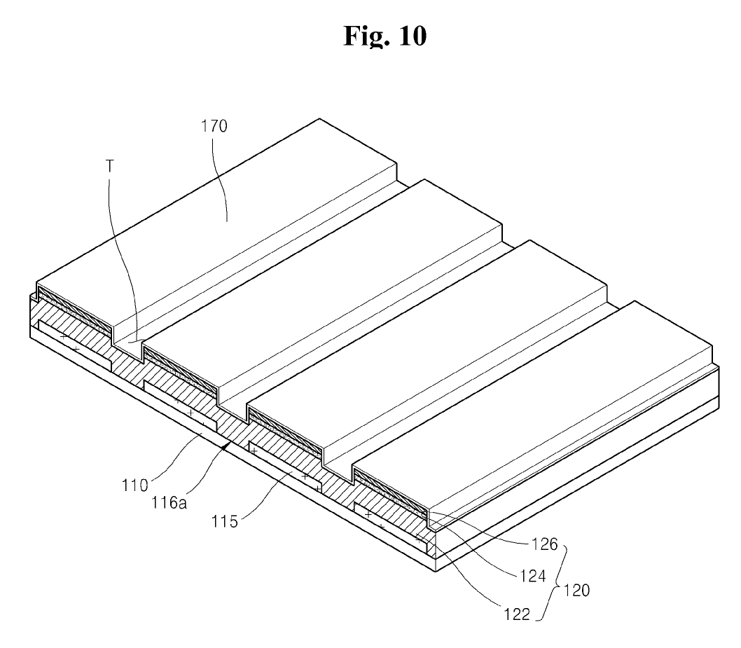

FIGS. 10 and 11 are perspective views showing a process of depositing and etching an insulating layer on a light-emitting structure, which includes the trench shown in FIG. 4, before the attachment of a bonding substrate, and FIG. 12 is a perspective view showing another embodiment of the insulating layer pattern shown in FIG. 11.

Referring to FIGS. 10 and 11, after the process shown in FIG. 4 has been completed, insulating layer patterns 170a may further be formed on the surface of the trenches T, that is, the bottom surface and sidewall of the trenches T, by depositing an insulating layer 170 of silicon oxide (SiO₂) or silicon oxide (SiO₂)/titanium oxide (TiO₂) on the surface of the light-emitting structure 120 having the trenches T formed therein, and patterning the insulating layer 170 using a mask (not shown). Such insulating layer patterns 170a function to prevent electric current from flowing in regions having the trenches T formed therein.

Meanwhile, as shown in FIG. 12, the insulating layer patterns 170a may be formed not only on the surface of the trenches T, but also on the edge of the light-emitting structure 120 in order to prevent the peeling of the ends of the light-emitting structure.

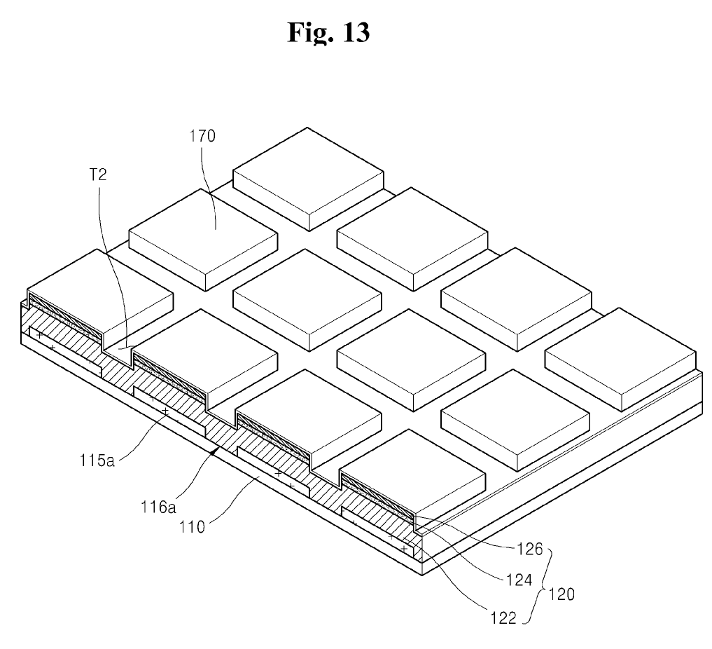

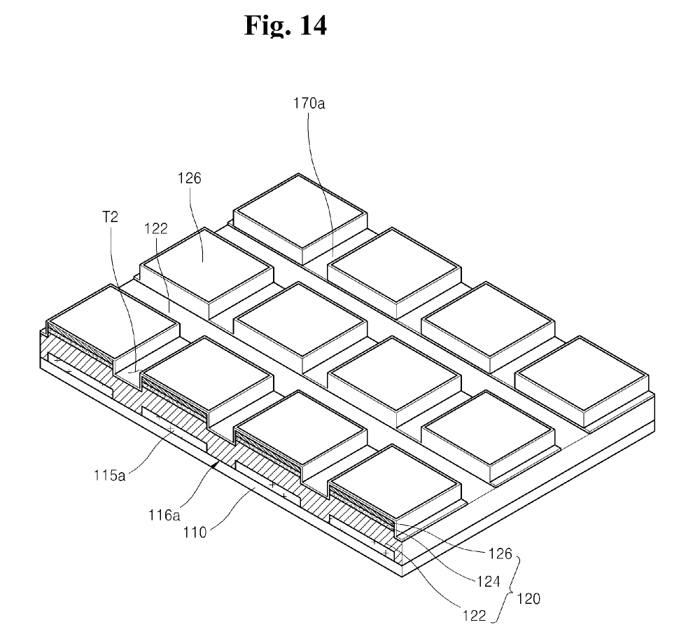

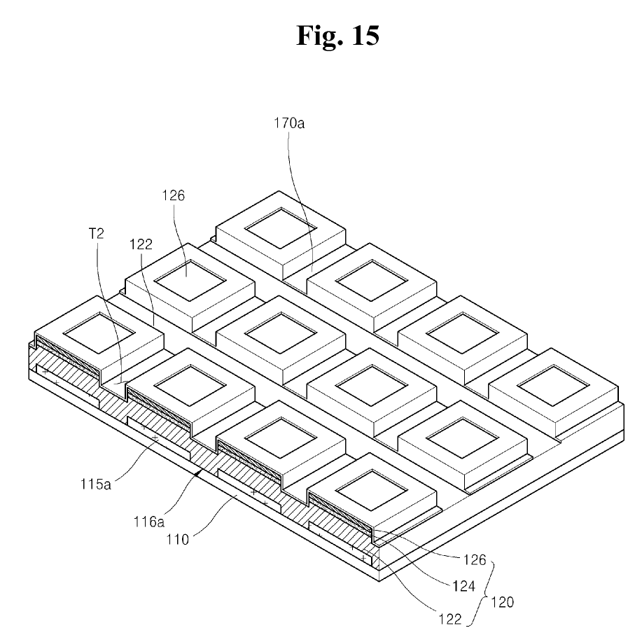

FIGS. 13 and 14 are perspective views showing a process of depositing and etching an insulating layer on a light-emitting structure, which includes the trench shown in FIG. 9, before the attachment of a bonding substrate, and FIG. 15 is a perspective view showing another embodiment of the insulating layer patterns shown in FIG. 14.

Referring to FIGS. 13 and 14, after the process shown in FIG. 9 has been completed, insulating layer patterns 170a may further be formed on the surface of second trenches T2, that is, the bottom surface and sidewall of the second trenches 170a, by depositing an insulating layer 170 of silicon oxide (SiO₂) or silicon oxide (SiO₂)/titanium oxide (TiO₂) on the surface of the light-emitting structure 120 having the second trenches T2 formed therein, and patterning the insulating layer 170 using a mask (not shown). Such insulating layer patterns 170a function to prevent electric current from flowing in regions having the second trenches T2 formed therein.

Meanwhile, as shown in FIG. 15, the insulating layer patterns 170a may be formed not only on the surface of the second trenches T2, but also on the edge of the light-emitting structure 120 in order to prevent the peeling of the ends of the light-emitting structure. Thereafter, transparent conductive patterns 140 and n-side bonding pads 150 may be formed, thereby fabricating a nitride semiconductor light-emitting device similar to the example shown in FIG. 16.

Although the preferred embodiments of the present invention has been described for illustrative purposes, those skilled in the art will appreciate that various modifications, additions and substitutions are possible, without departing from the scope and spirit of the invention. Thus, the scope of the present invention should be determined by the appended claims.

1. A method for manufacturing a nitride light-emitting device, comprising the steps of:
forming mask patterns having a width of 20-300 μm on a silicon substrate;
laterally growing a nitride on the silicon substrate exposed between the mask patterns, thereby forming a light-emitting structure comprising a first nitride semiconductor layer, an active layer and a second nitride semiconductor layer;
etching at least the second nitride semiconductor layer and the active layer in regions of the light-emitting structure between the mask patterns to form trenches;
attaching a bonding substrate to a surface of the light-emitting structure having the trenches formed therein; and
removing the silicon substrate and the mask patterns.

2. The method of claim 1, wherein the mask patterns are formed at a distance of 5-40 μm.

3. The method of claim 1, wherein the mask patterns are formed as stripe patterns.

4. The method of claim 1, wherein the mask patterns are formed as block patterns.

5. The method of claim 1, wherein a portion of the first nitride semiconductor layer is further etched in the etching step.

6. The method of claim 1, wherein the bonding substrate is a silicon substrate or a metal substrate.

7. The method of claim 1, further comprising a step of forming transparent conductive patterns on the first nitride semiconductor layer, after the step of removing the silicon substrate and the mask patterns, but before a step of forming n-side bonding pads.

8. The method of claim 1, further comprising a step of forming insulating layer patterns on the surface of the trenches, before the step of attaching the bonding substrate to the surface of the light-emitting structure having the trenches formed therein.

9. The method of claim 8, wherein the step of forming the insulating layer patterns on the surface of the trenches further comprises forming the insulating layer patterns on edges of the light-emitting structure.

10. A nitride light-emitting device comprising:
a light-emitting structure comprising a first nitride semiconductor layer, an active layer and a second nitride semiconductor layer from top to bottom, in which a plurality of trenches are formed up to at least the second nitride semiconductor layer and the active layer from bottom to top; and
a bonding substrate bonded to a bottom surface of the light-emitting structure,
wherein a width of the light-emitting structure between one trench and another trench adjacent thereto is 20-300 μm.

11. The nitride light-emitting device of claim 10, wherein the width of the trench is 5-40 μm.

12. The nitride light-emitting device of claim 10, wherein the light-emitting structure between one trench and another trench adjacent thereto is a stripe pattern or a block pattern.

13. The nitride light-emitting device of claim 10, wherein the light-emitting structure between one trench and another trench adjacent thereto has an inclined sidewall.

14. The nitride light-emitting device of claim 10, wherein the trenches are formed by performing etching up to at least a portion of the first nitride semiconductor layer.

15. The nitride light-emitting device of claim 10, wherein the bonding substrate is a silicon substrate or a metal substrate.

16. The nitride light-emitting device of claim 15, wherein the bonding substrate acts as a p-side electrode.

17. The nitride light-emitting device of claim 10, further comprising insulating layer patterns formed on the surface of the trenches.

18. The nitride light-emitting device of claim 10, wherein the insulating layer patterns are further formed at an edge of the bottom of the light-emitting structure.

19. The nitride light-emitting device of claim 18, wherein the insulating layer patterns are composed of a silicon oxide (SiO₂) layer or a layer formed by depositing silicon oxide (SiO₂) and titanium oxide (TiO₂).

20. The nitride light-emitting device of claim 10, wherein the first nitride semiconductor layer has a resistance of 0.02 Ω·cm to 0.1 Ω·cm and a carrier concentration of 2×10¹⁷ cm³ to 1×10¹⁸ cm³ in a portion ranging from the surface thereof to a depth of 30-500 nm therefrom.
